(19) United States
(12) Patent Application Publication
(10) Pub. No.: US 2021/0335584 A1
(43) Pub. Date: Oct. 28, 2021

(54) STAGE AND SUBSTRATE PROCESSING APPARATUS

(71) Applicant: TOKYO ELECTRON LIMITED, Tokyo (JP)

(72) Inventors: Masakatsu KASHIWAZAKI, Miyagi (JP); Toshifumi ISHIDA, Miyagi (JP); Ryo SASAKI, Miyagi (JP); Takehiro KATO, Miyagi (JP)

(21) Appl. No.: 17/274,294

(22) PCT Filed: Sep. 11, 2019
(86) PCT No.: PCT/JP2019/035707

§ 371 Date: Mar. 8, 2021

(30) Foreign Application Priority Data
Sep. 18, 2018 (JP) 2018-173679

(51) Int. Cl. H01J 37/32; H01L 21/683; F28F 3/12

(52) U.S. Cl. CPC H01J 37/32724; F28F 3/12; H01L 21/6833

(57) ABSTRACT

A stage includes: a substrate mounting member having a mounting surface on which a target substrate is mounted; a support member configured to support the substrate mounting member; a refrigerant flow path formed inside the support member along the mounting surface, and including a ceiling surface disposed on the mounting surface side, a bottom surface opposite to the ceiling surface, and an introduction port for introducing a refrigerant formed on the bottom surface; and a heat insulating member including at least a first planar portion covering a portion of the ceiling surface, which faces the introduction port, and a second planar portion covering an inner side surface of a curved portion of the refrigerant flow path.

### TECHNICAL FIELD

The present disclosure relates to a stage and a substrate processing apparatus.

### BACKGROUND

A substrate processing apparatus that performs substrate processing such as plasma processing on a target substrate such as a semiconductor wafer has been known. In such a substrate processing apparatus, in order to control the temperature of the target substrate, a refrigerant flow path is formed inside a stage along a mounting surface on which the target substrate is mounted. A ceiling surface of the refrigerant flow path is disposed on the mounting surface side of the stage, and a refrigerant introduction hole is formed on a bottom surface of the refrigerant flow path on the side opposite to the ceiling surface.

### PRIOR ART DOCUMENTS

### Patent Documents

Patent Document 1: Japanese laid-open publication No. 2014-195047

The present disclosure provides some embodiments of a technique capable of improving the temperature uniformity of a mounting surface on which a target substrate is mounted.

### SUMMARY

According to one embodiment of the present disclosure, there is provided a stage including: a substrate mounting member having a mounting surface on which a target substrate is mounted; a support member configured to support the substrate mounting member; a refrigerant flow path formed inside the support member along the mounting surface, and including a ceiling surface disposed on the mounting surface side, a bottom surface opposite to the ceiling surface, and an introduction port for introducing a refrigerant formed on the bottom surface; and a heat insulating member including at least a first planar portion covering a portion of the ceiling surface, which faces the introduction port, and a second planar portion covering an inner side surface of a curved portion of the refrigerant flow path.

According to the present disclosure, it is possible to show an effect of improving the temperature uniformity of a mounting surface on which a target substrate is mounted.

### BRIEF DESCRIPTION OF DRAWINGS

FIG. 1 is a schematic cross-sectional view illustrating the configuration of a substrate processing apparatus according to the present embodiment.

FIG. 2 is a schematic cross-sectional view illustrating an example of the configuration of a main part of a stage according to the present embodiment.

FIG. 3 is a plan view of the stage according to the present embodiment, as viewed from the mounting surface side.

FIG. 4 is a plan view illustrating an example of an installation mode of a heat insulating member according to the present embodiment.

FIG. 5 is a schematic cross-sectional view illustrating an example of the installation mode of the heat insulating member according to the present embodiment.

FIG. 6 is a perspective view illustrating an example of the configuration of the heat insulating member according to the present embodiment.

FIG. 7 is a diagram illustrating an example of a result of simulation on a temperature distribution of a mounting surface.

FIG. 8 is a perspective view illustrating a modification of the configuration of the heat insulating member.

### DETAILED DESCRIPTION

Various embodiments will now be described in detail with reference to the drawings. Throughout the drawings, the same or equivalent portions are denoted by the same reference numerals.

A substrate processing apparatus that performs substrate processing such as plasma processing on a target substrate such as a semiconductor wafer has been known. In such a substrate processing apparatus, in order to control the temperature of the target substrate, a refrigerant flow path is formed inside a stage along a mounting surface on which the target substrate is mounted. A ceiling surface of the refrigerant flow path is disposed on the mounting surface side of the stage, and a refrigerant introduction hole is formed on a bottom surface of the refrigerant flow path on the side opposite to the ceiling surface.

When the refrigerant flow path is formed inside the stage, the flow velocity of a refrigerant flowing through the refrigerant flow path may increase locally. For example, the flow velocity of the refrigerant increases locally in a portion of the ceiling surface of the refrigerant flow path facing the refrigerant introduction hole, or the inner side surface of a curved portion of the refrigerant flow path. When the flow velocity of the refrigerant increases locally, heat exchange between the refrigerant and the stage is locally promoted. As a result, the temperature uniformity of the mounting surface on which the target substrate is mounted may decrease in the stage. The decrease of the temperature uniformity of the mounting surface on which the target substrate is mounted is not desirable because it causes deterioration in the quality of the target substrate.

### [Configuration of Plasma Processing Apparatus]

First, a substrate processing apparatus will be described. The substrate processing apparatus is an apparatus that performs plasma processing on a target substrate. In the present embodiment, a case where the substrate processing apparatus is a plasma processing apparatus that performs plasma etching on a wafer will be described as an example.

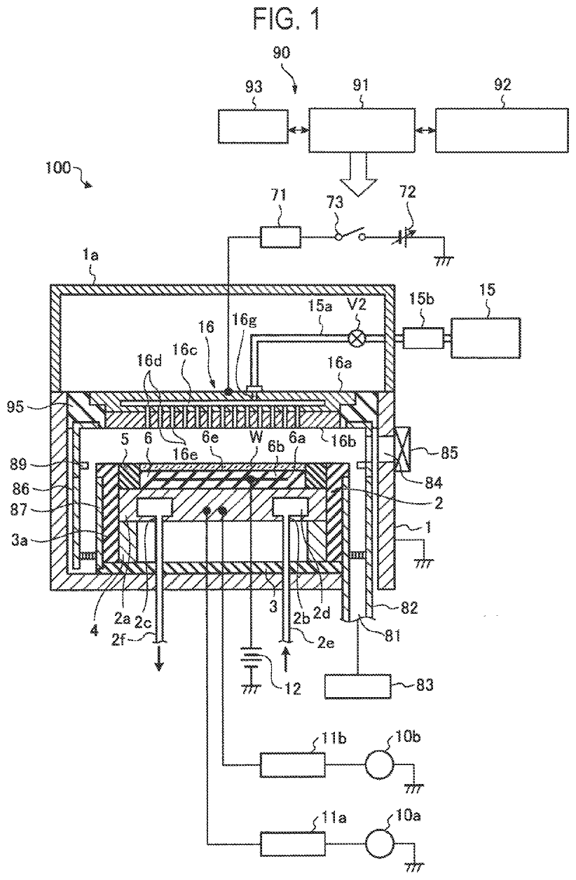

FIG. 1 is a schematic cross-sectional view illustrating the configuration of the substrate processing apparatus according to the present embodiment. The substrate processing apparatus 100 has a processing container 1 that is airtight and has an electrically ground potential. The processing container 1 has a cylindrical shape and is made of, for example, aluminum or the like. The processing container 1 defines a processing space in which plasma is generated. A stage 2 for supporting a semiconductor wafer (hereinafter simply referred to as a “wafer”) W, which is a target substrate, in a horizontal posture is installed in the processing container 1. The stage 2 includes a base 2a and an electrostatic chuck (ESC) 6. The electrostatic chuck 6 corresponds to a substrate mounting member, and the base 2a corresponds to a support member.

The base 2a is formed in substantially a circular columnar shape and is made of a conductive metal such as aluminum. The base 2a has a function as a lower electrode. The base 2a is supported by a support base 4. The support base 4 is supported by a support plate 3 made of, for example, quartz or the like. A cylindrical inner wall member 3a made of, for example, quartz or the like, is installed around the base 2a and the support base 4.

A first RF power supply 10a is connected to the base 2a via a first matching device 11a, and a second RF power supply 10b is connected to the base 2a via a second matching device 11b. The first RF power supply 10a is for generating plasma, and radio frequency power having a predetermined frequency is supplied from the first RF power supply 10a to the base 2a of the stage 2. Further, the second RF power supply 10b is for ion attraction (for bias), and radio frequency power having a predetermined frequency lower than that of the first RF power supply 10a is supplied from the second RF power supply 10b to the base 2a of the stage 2.

The electrostatic chuck 6 is formed in a disc shape, and has a flat upper surface. The upper surface serves as a mounting surface 6e on which the wafer W is mounted. The electrostatic chuck 6 is configured to include an insulator 6b and an electrode 6a interposed in the insulator 6b, and a DC power supply 12 is connected to the electrode 6a. Then, when a DC voltage is applied from the DC power supply 12 to the electrode 6a, the wafer W is adsorbed by a Coulomb force.

Further, an annular edge ring 5 is installed on the outside of the electrostatic chuck 6. The edge ring 5 is made of, for example, single crystal silicon and is supported by the base 2a. The edge ring 5 is also called a focus ring.

A refrigerant flow path 2d is formed inside the base 2a. An introduction flow path 2b is connected to one end of the refrigerant flow path 2d, and a discharge flow path 2c is connected to the other end of the refrigerant flow path 2d. The introduction flow path 2b and the discharge flow path 2c are connected to a chiller unit (not shown) via a refrigerant inlet pipe 2e and a refrigerant outlet pipe 2f, respectively. The refrigerant flow path 2d is located below the wafer W and functions to absorb heat of the wafer W. The substrate processing apparatus 100 is configured to be able to control the stage 2 to a predetermined temperature by circulating, in the refrigerant flow path 2d, a refrigerant supplied from the chiller unit, for example, an organic solvent such as cooling water or Galden. The structures of the refrigerant flow path 2d, the introduction flow path 2b, and the discharge flow path 2c will be described later.

Further, the substrate processing apparatus 100 may be configured to be able to control the temperature individually by supplying a cold heat transfer gas to the rear surface side of the wafer W. For example, a gas supply pipe for supplying the cold heat transfer gas (backside gas) such as a helium gas may be installed on the rear surface of the wafer W so as to penetrate the stage 2 and the like. The gas supply pipe is connected to a gas supply source (not shown). With such a configuration, the wafer W adsorbed and held by the electrostatic chuck 6 on the upper surface of the stage 2 is controlled to a predetermined temperature.

On the other hand, a shower head 16 having a function as an upper electrode is installed above the stage 2 so as to face the stage 2 in parallel. The shower head 16 and the stage 2 function as a pair of electrodes (the upper electrode and the lower electrode).

The shower head 16 is installed in the top wall portion of the processing container 1. The shower head 16 includes a main body portion 16a and an upper ceiling plate 16b forming an electrode plate, and is supported on the upper portion of the processing container 1 via an insulating member 95. The main body portion 16a is made of a conductive material, for example, aluminum whose surface is anodized, and is configured to be able to detachably support the upper ceiling plate 16b under the conductive material.

A gas diffusion chamber 16c is installed inside the main body portion 16a. Further, in the bottom portion of the main body portion 16a, a large number of gas passage holes 16d are formed so as to be located at the lower portion of the gas diffusion chamber 16c. Further, the upper ceiling plate 16b is installed so that gas introduction holes 16e, which penetrate the upper ceiling plate 16b in the thickness direction, overlap the above-mentioned gas passage holes 16d. With such a configuration, a process gas supplied into the gas diffusion chamber 16c is dispersed and supplied in a shower shape in the processing container 1 through the gas passage holes 16d and the gas introduction holes 16e.

The main body portion 16a is formed with a gas introduction port 16g for introducing the process gas into the gas diffusion chamber 16c. One end of a gas supply pipe 15a is connected to the gas introduction port 16g. A process gas supply source (gas supplier) 15 for supplying the process gas is connected to the other end of the gas supply pipe 15a. A mass flow controller (MFC) 15b and an opening/closing valve V2 are installed in the gas supply pipe 15a sequentially from the upstream side. The process gas for plasma etching is supplied from the process gas supply source 15 into the gas diffusion chamber 16c via the gas supply pipe 15a. The process gas is dispersed in a shower shape and supplied in the processing container 1 from the gas diffusion chamber 16c through the gas passage holes 16d and the gas introduction holes 16e.

A variable DC power supply 72 is electrically connected to the shower head 16, which serves as the above-mentioned upper electrode, via a low-pass filter (LPF) 71. The variable DC power supply 72 is configured to be able to turn on/off power feeding by an on/off switch 73. A current/voltage of the variable DC power supply 72 and the turning on/off of the on/off switch 73 are controlled by a controller 90 to be described later. As will be described later, when radio frequency is applied from the first RF power supply 10a and the second RF power supply 10b to the stage 2 to generate plasma in the processing space, the on/off switch 73 is turned on by the controller 90, as necessary, to apply a predetermined DC voltage to the shower head 16 which serves as the upper electrode.

A cylindrical ground conductor 1a is installed so as to extend above the height position of the shower head 16 from a side wall of the processing container 1. The cylindrical ground conductor 1a has a ceiling wall at the upper portion thereof.

An exhaust port 81 is formed at the bottom of the processing container 1. A first exhaust device 83 is connected to the exhaust port 81 via an exhaust pipe 82. The first exhaust device 83 has a vacuum pump and is configured to be able to depressurize the interior of the processing container 1 to a predetermined degree of vacuum by actuating the vacuum pump. On the other hand, a loading/unloading port 84 of the wafer W is formed on the side wall of the processing container 1, and a gate valve 85 for opening/closing the loading/unloading port 84 is installed in the loading/unloading port 84.

A deposition shield 86 is installed in the inner side of the side portion of the processing container 1 along the inner wall surface of the processing container 1. The deposition shield 86 prevents etching byproducts (deposition) from adhering to the processing container 1. A conductive member (GND block) 89 connected to be able to control a potential with respect to the ground is installed at a height position of the deposition shield 86 having substantially the same height as the wafer W, thereby preventing abnormal discharge. Further, a deposition shield 87 extending along the inner wall member 3a is installed at the lower end of the deposition shield 86. The deposition shields 86 and 87 are detachable.

The operation of the substrate processing apparatus 100 as configured above is collectively controlled by the controller 90. The controller 90 includes a process controller 91 including a CPU for controlling various parts of the substrate processing apparatus 100, a user interface 92, and a storage part 93.

The user interface 92 includes a keyboard for a process manager to input commands for managing the substrate processing apparatus 100, a display for visualizing and displaying the operating status of the substrate processing apparatus 100, and the like.

The storage part 93 stores a control program (software) for realizing various processes executed by the substrate processing apparatus 100 under the control of the process controller 91, and recipes such as process condition data are stored. Then, as necessary, an arbitrary recipe is called from the storage part 93 in response to an instruction from the user interface 92 or the like and is executed by the process controller 91, so that a desired process in the substrate processing apparatus 100 is performed under the control of the process controller 91. In addition, the control program and the recipes such as the process condition data may use ones stored in a computer-readable storage medium (for example, a hard disk, a CD, a flexible disk, a semiconductor memory, etc.) and the like, or may use ones transmitted online from other apparatuses at any time, for example via a dedicated line.

### [Configuration of Stage]

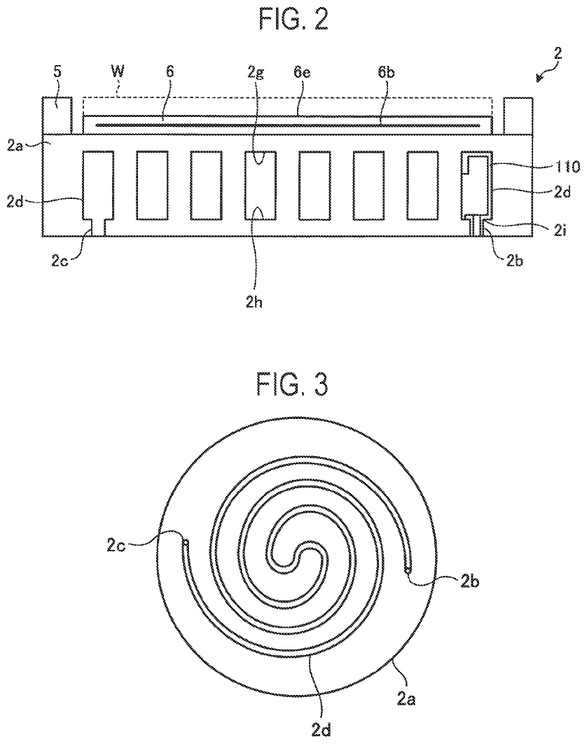

Next, the configuration of the main part of the stage 2 will be described with reference to FIG. 2. FIG. 2 is a schematic cross-sectional view illustrating an example of the configuration of the main part of the stage 2 according to the present embodiment.

The stage 2 has the base 2a and the electrostatic chuck 6. The electrostatic chuck 6 is formed in a disk shape and is fixed to the base 2a so as to be coaxial with the base 2a. The upper surface of the electrostatic chuck 6 is the mounting surface 6e on which the wafer W is mounted.

The refrigerant flow path 2d is formed inside the base 2a along the mounting surface 6e. The substrate processing apparatus 100 is configured to be able to control the temperature of the stage 2 by allowing the refrigerant to flow through the refrigerant flow path 2d.

FIG. 3 is a plan view of the stage 2 according to the present embodiment, as viewed from the mounting surface 6e side. As illustrated in FIG. 3, for example, the refrigerant flow path 2d is formed to be spirally curved in a region corresponding to the mounting surface 6e inside the base 2a. As a result, the substrate processing apparatus 100 can control the temperature of the wafer W over the entire mounting surface 6e of the stage 2.

Returning to FIG. 2, the introduction flow path 2b and the discharge flow path 2c are connected to the refrigerant flow path 2d from the rear surface side with respect to the mounting surface 6e. The introduction flow path 2b introduces the refrigerant into the refrigerant flow path 2d, and the discharge flow path 2c discharges the refrigerant flowing through the refrigerant flow path 2d. For example, the introduction flow path 2b extends from the rear surface side with respect to the mounting surface 6e of the stage 2 so that the extension direction of the introduction flow path 2b is orthogonal to the flow direction of the refrigerant flowing through the refrigerant flow path 2d, and is connected to the refrigerant flow path 2d. Further, the discharge flow path 2c extends from the rear surface side with respect to the mounting surface 6e of the stage 2 so that the extension direction of the discharge flow path 2c is orthogonal to the flow direction of the refrigerant flowing through the refrigerant flow path 2d, and is connected to the refrigerant flow path 2d.

A ceiling surface 2g of the refrigerant flow path 2d is disposed on the rear surface side of the mounting surface 6e. An introduction port 2i for introducing the refrigerant is formed on the bottom surface 2h of the refrigerant flow path 2d on the side opposite to the ceiling surface 2g. The introduction port 2i of the refrigerant flow path 2d forms a connecting portion between the refrigerant flow path 2d and the introduction flow path 2b. A heat insulating member 110 made of a heat insulating material is installed in the introduction port 2i of the refrigerant flow path 2d. Examples of the heat insulating material may include resins, rubbers, ceramics, and metals.

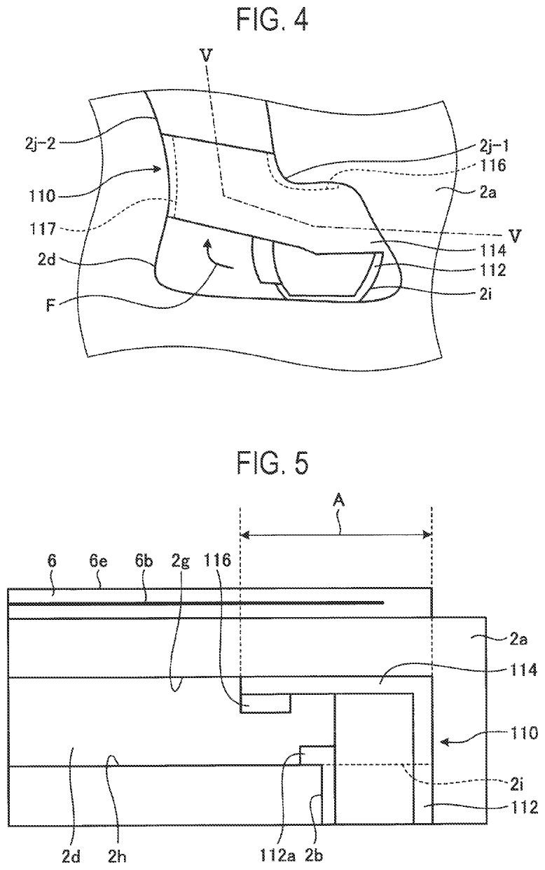

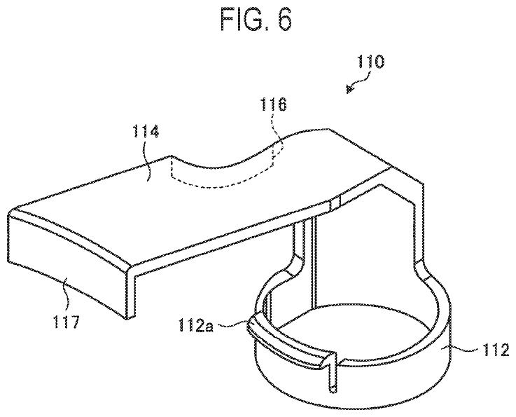

FIG. 4 is a plan view illustrating an example of an installation mode of the heat insulating member 110 according to the present embodiment. FIG. 5 is a schematic cross-sectional view illustrating an example of the installation mode of the heat insulating member 110 according to the present embodiment. FIG. 6 is a perspective view illustrating an example of the configuration of the heat insulating member 110 according to the present embodiment. The structure illustrated in FIG. 4 corresponds to a structure in the vicinity of the connection portion (that is, the introduction port 2i of the refrigerant flow path 2d) between the refrigerant flow path 2d and the introduction flow path 2b illustrated in FIG. 3. Further, FIG. 5 corresponds to a cross-sectional view taken along line V-V of the base 2a illustrated in FIG. 4.

As illustrated in FIGS. 4 to 6, the heat insulating member 110 has a main body portion 112, a first planar portion 114, and second planar portions 116 and 117. The main body portion 112 is detachably attached to the introduction port 2i of the refrigerant flow path 2d and is connected to the first planar portion 114. The main body portion 112 has a fixing claw 112a for fixing the main body portion 112 to the bottom surface 2h of the refrigerant flow path 2d in a state where the main body portion 112 is attached to the introduction port of the refrigerant flow path 2d.

The first planar portion 114 extends from the main body portion 112 and covers at least a portion of the ceiling surface 2g of the refrigerant flow path 2d, which faces the introduction port 2i. In the present embodiment, the first planar portion 114 covers a predetermined portion A of the ceiling surface 2g of the refrigerant flow path 2d. The predetermined portion A is obtained by expanding, by a predetermined size, a portion of the ceiling surface 2g of the refrigerant flow path 2d, which faces the introduction port 2i, in a direction in which the refrigerant flows (a direction indicated by an arrow F in FIG. 4).

The second planar portions 116 and 117 extend from the first planar portion 114 and cover the inner side surfaces (for example, the inner side surface 2j-1 or the inner side surface 2j-2) of the curved portion of the refrigerant flow path 2d. In the present embodiment, the second planar portion 116 covers the inner side surface 2j-1 continuous with the predetermined portion A, and the second planar portion 117 covers the inner side surface 2j-2 continuous with the predetermined portion A.

When the refrigerant flow path 2d is formed inside the stage 2 (that is, inside the base 2a), the flow velocity of the refrigerant flowing through the refrigerant flow path 2d may increase locally. For example, the flow velocity of the refrigerant increases locally in the portion of the ceiling surface 2g of the refrigerant flow path 2d, which faces the introduction port 2i, or the inner side surface (for example, the inner side surface 2j-1 or the inner side surface 2j-2) of the curved portion of the refrigerant flow path 2d. When the flow velocity of the refrigerant increases locally, heat exchange between the refrigerant and the base 2a is locally promoted. As a result, the temperature uniformity of the mounting surface 6e on which the wafer W is mounted may be impaired in the stage 2.

Therefore, in the substrate processing apparatus 100, the heat insulating member 110 is installed in the introduction port 2i of the refrigerant flow path 2d. That is, the first planar portion 114 of the heat insulating member 110 covers at least the portion of the ceiling surface 2g of the refrigerant flow path 2d, which faces the introduction port 2i. Further, the second planar portions 116 and 117 of the heat insulating member 110 cover the inner side surfaces 2j-1 and 2j-2 of the curved portion of the refrigerant flow path 2d. As a result, since the heat insulating member 110 can cover the portion of the ceiling surface 2g of the refrigerant flow path 2d, which faces the introduction port 2i, and the inner side surfaces 2j-1 and 2j-2 of the curved portion of the refrigerant flow path 2d, the increase in the flow velocity of the refrigerant can be suppressed in these regions. This makes it possible to prevent the heat exchange between the refrigerant and the base 2a from being locally promoted. As a result, the temperature uniformity of the mounting surface 6e on which the wafer W is mounted can be improved.

### [Simulation on Temperature Distribution of Mounting Surface]

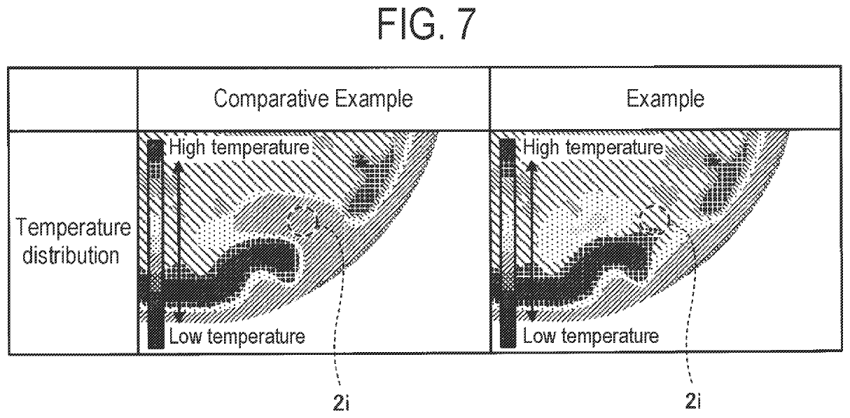

FIG. 7 is a diagram illustrating an example of a result of simulation on the temperature distribution of the mounting surface 6e. In FIG. 7, a “Comparative Example” shows a temperature distribution when the heat insulating member 110 is not installed in the introduction port 2i of the refrigerant flow path 2d. In FIG. 7, an “Example” shows a temperature distribution when the heat insulating member 110 is installed in the introduction port 2i of the refrigerant flow path 2d. In FIG. 7, the position of the introduction port 2i of the refrigerant flow path 2d is indicated by a circle of a broken line.

As illustrated in FIG. 7, when the heat insulating member 110 is not installed in the introduction port 2i of the refrigerant flow path 2d, the temperature of a region of the mounting surface 6e corresponding to the introduction port 2i of the refrigerant flow path 2d is lower than the temperature of the other regions. It is considered that this is because the flow velocity of the refrigerant increases locally on the portion of the ceiling surface 2g of the refrigerant flow path 2d, which faces the introduction port 2i, or the inner side surfaces 2j-1 and 2j-2 of the curved portion of the refrigerant flow path 2d, so that the heat exchange between the refrigerant and the base 2a is promoted locally.

On the other hand, when the heat insulating member 110 is installed in the introduction port 2i of the refrigerant flow path 2d, the temperature of the region of the mounting surface 6e corresponding to the introduction port 2i of the refrigerant flow path 2d rises to the same temperature as the other regions. That is, the temperature uniformity of the mounting surface 6e is improved more when the heat insulating member 110 is installed in the introduction port 2i of the refrigerant flow path 2d than when the heat insulating member 110 is not installed in the introduction port 2i of the refrigerant flow path 2d. It is considered that this is because the heat insulating member 110 covers the portion of the ceiling surface 2g of the refrigerant flow path 2d, which faces the introduction port 2i, and the inner side surfaces 2j-1 and 2j-2 of the curved portion of the refrigerant flow path 2d, so that the heat exchange between the refrigerant and the base 2a is suppressed in these regions.

As described above, the stage 2 according to the present embodiment has the electrostatic chuck 6, the base 2a, the refrigerant flow path 2d, and the heat insulating member 110. The electrostatic chuck 6 has the mounting surface 6e on which the wafer W is mounted. The base 2a supports the electrostatic chuck 6. The refrigerant flow path 2d is formed inside the base 2a along the mounting surface 6e, and the refrigerant introduction port 2i is formed on the bottom surface 2h on the side opposite to the ceiling surface 2g disposed on the mounting surface 6e side. The heat insulating member 110 has the first planar portion 114 and the second planar portions 116 and 117. The first planar portion 114 covers at least the portion of the ceiling surface 2g of the refrigerant flow path 2d, which faces the introduction port 2i. The second planar portions 116 and 117 cover the inner side surfaces 2j-1 and 2j-2 of the curved portion of the refrigerant flow path 2d. As a result, the stage 2 according to the present embodiment can improve the temperature uniformity of the mounting surface 6e on which the wafer W is mounted.

Although the embodiment has been described above, various modifications can be made without being limited to the above-described embodiment.

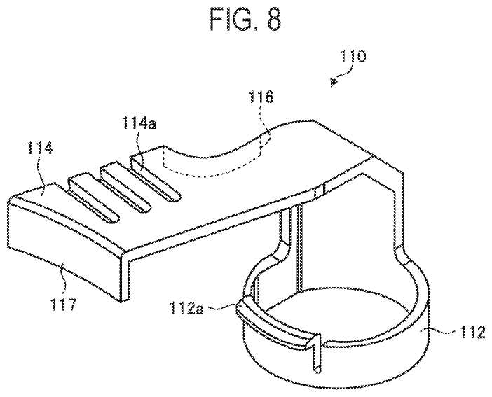

For example, in the heat insulating member 110 of the embodiment, a groove may be formed in the first planar portion 114. FIG. 8 is a perspective view illustrating a modification of the configuration of the heat insulating member 110. Grooves 114a are formed in the first planar portion 114 illustrated in FIG. 8. The groove 114a retains the refrigerant. The refrigerant retained in the groove 114a is heated to a high temperature by heat introduced from the ceiling surface 2g of the refrigerant flow path 2d. That is, the groove 114a can further suppress the heat exchange between the refrigerant flowing through the refrigerant flow path 2d and the base 2a by retaining the heated refrigerant having high temperature. Further, for example, grooves may be formed in the second planar portions 116 and 117. In short, a groove may be formed in at least one of the first planar portion and the second planar portion.

Further, in the embodiment, the case where the heat insulating member 110 is installed in the introduction port 2i of the refrigerant flow path 2d has been described as an example, but the present disclosure is not limited thereto. For example, the heat insulating member 110 may be installed at an arbitrary position in the refrigerant flow path 2d within an installable range. For example, the heat insulating member 110 may be installed only on the inner side surfaces 2j-1 and 2j-2 of the curved portion of the refrigerant flow path 2d. In this case, the heat insulating member 110 has the second planar portions that cover the inner side surfaces 2j-1 and 2j-2 of the curved portion of the refrigerant flow path 2d, and the main body portion 112 and the first planar portion 114 may be omitted.

Further, in the embodiment, the case where the heat insulating member 110 is installed in the introduction port 2i of the refrigerant flow path 2d formed inside the stage 2 has been described as an example, but the present disclosure is not limited thereto. For example, when a refrigerant flow path is formed in the shower head 16 serving as the upper electrode, the heat insulating member 110 may be installed in an introduction port of the refrigerant flow path formed in the shower head 16. As a result, the temperature uniformity of the surface of the shower head 16 facing the stage 2 can be improved.

Further, in the embodiment, the case where the substrate processing apparatus 100 is the plasma processing apparatus that performs plasma etching has been described as an example, but the present disclosure is not limited thereto. For example, the substrate processing apparatus 100 may be a substrate processing apparatus that performs film formation and improvement of film quality.

Further, although the substrate processing apparatus 100 according to the embodiment is a plasma processing apparatus using capacitively-coupled plasma (CCP), any plasma source may be applied to the plasma processing apparatus. For example, examples of the plasma source applied to the plasma processing apparatus may include inductively-coupled plasma (ICP), radial line slot antenna (RLSA), electron cyclotron resonance plasma (ECR), helicon wave plasma (HWP), and the like.

### EXPLANATION OF REFERENCE NUMERALS

1: processing container, 2: stage, 2a: base, 4: introduction flow path, 2d: refrigerant flow path, 2g: ceiling surface, 2h: bottom surface, 2i: introduction port, 6: electrostatic chuck, 6e: mounting surface, 100: substrate processing apparatus, 110: heat insulating member, 112: main body portion, 114: first planar portion, 114a: groove, 116, 117: second planar portion, W: wafer

1. A stage comprising:
a substrate mounting member having a mounting surface on which a target substrate is mounted;
a support member configured to support the substrate mounting member;
a refrigerant flow path formed inside the support member along the mounting surface, and including a ceiling surface disposed on the mounting surface side, a bottom surface opposite to the ceiling surface, and an introduction port for introducing a refrigerant formed on the bottom surface; and
a heat insulating member including at least a first planar portion covering a portion of the ceiling surface, which faces the introduction port, and a second planar portion covering an inner side surface of a curved portion of the refrigerant flow path.

2. The stage of claim 1, wherein a groove is formed in at least one of the first planar portion and the second planar portion.

3. The stage of claim 2, wherein the heat insulating member is detachably attached to the introduction port of the refrigerant flow path and further includes a main body portion connected to the first planar portion.

4. The stage of claim 1, wherein the heat insulating member is detachably attached to the introduction port of the refrigerant flow path and further includes a main body portion connected to the first planar portion.

5. A stage comprising:
a substrate mounting member having a mounting surface on which a target substrate is mounted;
a support member configured to support the substrate mounting member;
a refrigerant flow path formed inside the support member along the mounting surface, and including a ceiling surface disposed on the mounting surface side, a bottom surface opposite to the ceiling surface, and an introduction port for introducing a refrigerant formed on the bottom surface; and
a heat insulating member including a planar portion covering an inner side surface of a curved portion of the refrigerant flow path.

6. A substrate processing apparatus comprising:
a stage including:
a substrate mounting member having a mounting surface on which a target substrate is mounted;
a support member configured to support the substrate mounting member;
a refrigerant flow path formed inside the support member along the mounting surface, and including a ceiling surface disposed on the mounting surface side, a bottom surface opposite to the ceiling surface, and an introduction port for introducing a refrigerant formed on the bottom surface; and
a heat insulating member including at least a first planar portion covering a portion of the ceiling surface, which faces the introduction port, and a second planar portion covering an inner side surface of a curved portion of the refrigerant flow path.
